(19) United States
(12) Patent Application Publication
(10) Pub. No.: US 2009/0009175 A1
(43) Pub. Date: Jan. 8, 2009

(54) CURRENT-MEASURING CLAMP ON SENSOR IN ELECTROMECHANICAL RELAYS

(76) Inventor: Hamit Semati, Ankara (TR)

Correspondence Address: Saul Ewing LLP (Philadelphia), Attn: Patent Docket Clerk, 2 North Second St., Harrisburg, PA, 17101, US

(21) Appl. No.: 12/278,358

(22) PCT Filed: Feb. 6, 2007
(86) PCT No.: PCT/TR07/00008

§ 371 Date: Aug. 5, 2008

(30) Foreign Application Priority Data
Feb. 7, 2006 (TR) 2006/00517

(51) Int. Cl. G01R 15/20

(52) U.S. Cl. 324/418

(57) ABSTRACT

This invention relates to the system that detects the origin of relay or relays where failures are seen in electromechanical relays, and ensuring the repair of failure at the shortest time. System developed by this invention consists of a clamp on sensor handle, clamp on sensor ground, mumetal, magnetic area measuring sensor, clamp on sensor cable and socket. Signals sent to the recorder through the system are measured in ampere and this information is transferred to the computer.

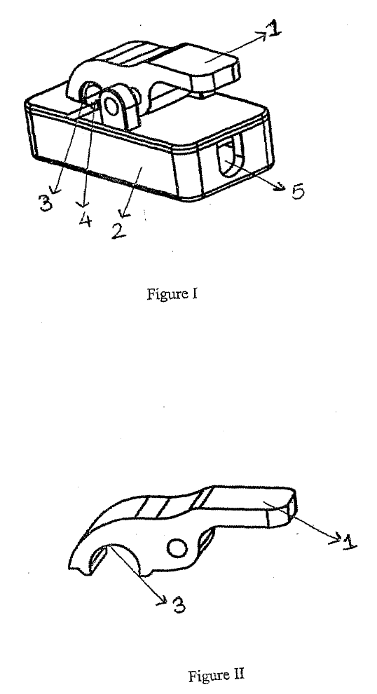

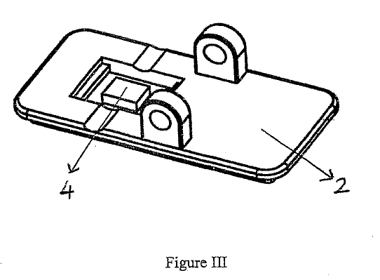

This invention relates to the system that detects the origin of relay or relays where failures are seen in electromechanical relays, and ensuring the repair of failure at the shortest time.

Electricity produced in production sites like dams and power plants are sent to intermediate stations for transmission to homes and business.

Voltage of the electricity received in high voltages from electricity production sites are reduced and made usable in intermediate stations. Electricity distribution is made to homes, businesses and factories from intermediate stations. Intermediate stations house relays.

Huge electricity network needs to be protected against very frequent failures. Failures on lines are caused due to electrical contact of each line with each other or their contact with the ground. As for other electrical line failures; they are caused by lightning strikes, wild storms and car accidents. The duty of relays is to sense failures and protect the street-level distribution system by putting the circuit cutter into operation.

Relays are divided into 2 based on their communicative abilities. Microprocessor relays can communicate. Electromechanical relays cannot communicate. 80% of relays in the market are electromechanical relays. Electromechanical relays are reliable and have long service lives, however they are made to communicate electronically with external devices in order to report their activities.

Relays increase by electricity users and capacity. There may be thousands of relays in an intermediate station. In case of any failure, number of flags on relays increases. When the number of flags increases, one cannot understand in which phase or relay the failure is. In case of failure, each relay is opened and closed one by one to understand from which relay or relays the failure originates. This is a long and meticulous job and houses and businesses may remain interrupted due to the delay in finding the failure. Failures in relays may sometimes be momentary too.

In the PCT application no WO2006/006794 and European patent application no EP0647853, measurement of current passing through the cables is a costly operation and at the same time mechanism developed cover a very large space. Sensor developed to measure magnetic area has been described in U.S. Pat. No. 6,545,462. The system described in this application is only one of the units included in our invention.

With this invention, it becomes possible to easily determine whether the failures in intermediate stations are momentary or permanent and where they originate from.

This invention ensures the transmission of direct and alternative current passing through the cables to the computer environment, that is, electronic transmission through external devices. So far, various methods were developed to measure the current passing through the cables.

However, systems created by these methods are too large to be used on electromechanical relays, more complicated, more expensive, with no wide and rapid sensor capacity.

In the electromechanical relays developed with this invention, parts listed in the figures prepared to better describe current-measuring clamp on sensor are separately numbered.

Description of each figure and part is given below.

FIG. I—overview of the current-measuring clamp on sensor in electromechanical relays

FIG. II—moving part of the current-measuring clamp on sensor in electromechanical relays

FIG. III—fixed part of the current-measuring clamp on sensor in electromechanical relays

1—clamp on sensor handle
2—clamp on sensor ground
3—mumetal
4—sensor measuring magnetic area
5—clamp on sensor cable inlet

When we press on the clamp on sensor handle (1), sensor (4) measuring the mumetal (3) and magnetic area opens, and the system is attached to the cable whose current will be measured.

There is the clamp on sensor handle and mumetal in the moving part of the clamp on sensor. Mumetal (3) is a nickel and cadmium mixture. Thanks to mumetal increasing the magnitude of magnetic area, it is possible to make measurement in low amperes as well. Besides, mumetal also prevents the magnetic area coming from outside, and thanks to this errors that might arise with the sensing of magnetic areas on surrounding cables are prevented. Placed circularly on the clamp on sensor handle, mumetal may be in different dimensions. There is a sensor (4) measuring magnetic area on the clamp on sensor ground (2). Hall effect Ic may be used as a sensor measuring magnetic area in addition to all sorts of sensors measuring magnetic area. Sensor measuring magnetic area may be placed on clamp on sensor ground or on the clamp on sensor handle. In case the sensor measuring magnetic area is placed on the clamp on sensor handle, mumetal may be placed on clamp on sensor ground. If there is current in the measured cable, magnetic areas are formed around the cable and this magnetic area is in direct proportion to the passing current.

Signals received by sensor measuring magnetic area are measured in volts, transmitted through the clamp on sensor cable (5) and transferred to the recorder through the socket. The recorder measures the received voltage in ampere and transfers these date to the computer. Through appropriate software, one can understand in which relay or relays the failure is. When there is a failure in the electromechanical relays in intermediate stations, thanks to the system developed with this invention, it is possible to easily understand on which relay the failure is and detect temporary failures.

Clamp on sensor handle and clamp on sensor ground in current-measuring clamp on sensor on electro-mechanical relays may be made by all sorts of metals.

1-5. (canceled)

6. A non-intrusive current sensor comprising:
a main housing;
a clamp movably mounted to said housing, said clamp defining a space for removably accepting an electrical wire; and
a non-intrusive current sensor in said main housing for detecting current in an electrical wire positioned in said space.

7. The current sensor of claim 6 wherein said non-intrusive current sensor is a Hall-effect sensor.

8. The current sensor of claim 7 further comprising a mumetal disposed adjacent the space.

9. The current sensor of claim 7 further comprising a cable socket for accepting a cable.

10. The current sensor of claim 6 wherein the sensor is connected to output a signal indicative of the current detected via said cable socket.

11. The current sensor of claim 10 further comprising:
a recorder coupled to said clamp socket for recording said signal.

12. The current sensor of claim 11 further comprising:
a computer coupled to said recorder.

13. The current sensor of claim 12 wherein the current sensor senses current by measuring a voltage.

14. The current sensor of claim 13 wherein the recorder converts the measured voltage into amperes.
